(19) United States
(12) Patent Application Publication
(10) Pub. No.: US 2025/0293151 A1
(43) Pub. Date: Sep. 18, 2025

(54) SEMICONDUCTOR DEVICE

(71) Applicant: Renesas Electronics Corporation, Tokyo (JP)

(72) Inventors: Yasutaka NAKASHIBA, Tokyo (JP); Takayuki IGARASHI, Tokyo (JP); Tatsuo KASAOKA, Tokyo (JP); Yosuke WATANABE, Tokyo (JP)

(21) Appl. No.: 19/070,106

(22) Filed: Mar. 4, 2025

(30) Foreign Application Priority Data
Mar. 14, 2024 (JP) 2024-039836

(51) Int. Cl. H01L 23/522; H01L 21/768; H01L 23/528; H01L 23/532; H01L 23/58; H10D 1/20

(52) U.S. Cl. CPC H01L 23/5227; H01L 23/5283; H01L 23/585; H01L 21/76885; H01L 23/53214; H10D 1/20

(57) ABSTRACT

A semiconductor device includes a semiconductor substrate and a multilayer wiring layer disposed on the semiconductor substrate. The semiconductor substrate includes, in plan view, a coil region and a peripheral region surrounding the coil region. The multilayer wiring layer includes a first coil, a second coil, a third coil, a fourth coil, and a metal film. The first coil and the second coil are formed in a first wiring layer being one of the plurality of wiring layers disposed on the coil region. The third coil and the fourth coil are formed in a second wiring layer being another one of the plurality of wiring layers disposed on the coil region. The second wiring layer is disposed above the first wiring layer. The third coil and the fourth coil are disposed so as to face the first coil and the second coil, respectively.

### CROSS-REFERENCE TO RELATED APPLICATIONS

The disclosure of Japanese Patent Application No. 2024-039836 filed on Mar. 14, 2024 including the specification, drawings and abstract is incorporated herein by reference in its entirety.

### BACKGROUND

The present disclosure relates to a semiconductor device.

There are disclosed techniques listed below.
[Patent Document 1] International Publication No. 2014-097425

Patent Document 1 discloses a semiconductor device. The semiconductor device disclosed in Patent Document 1 includes a plurality of transformers. The transformer is formed of coils facing each other with an insulating layer therebetween. Each of the plurality of transformers forms a channel for transmitting and receiving a signal.

### SUMMARY

In the semiconductor device disclosed in Patent Document 1, the amount of warping can become large. Other objects and novel features will become apparent from the description of the present specification and the accompanying drawings.

The semiconductor device of the present disclosure includes a semiconductor substrate and a multilayer wiring layer disposed on the semiconductor substrate. The semiconductor substrate includes, in plan view, a coil region and a peripheral region surrounding the coil region. The multilayer wiring layer includes a first coil, a second coil, a third coil, a fourth coil, and a metal film. The multilayer wiring layer includes a plurality of wiring layers. The first coil and the second coil are formed in a first wiring layer being one of the plurality of wiring layers disposed on the coil region. The third coil and the fourth coil are formed in a second wiring layer being another one of the plurality of wiring layers disposed on the coil region. The second wiring layer is disposed above the first wiring layer. The third coil and the fourth coil are disposed so as to face the first coil and the second coil, respectively. The distance between the upper surface of the first wiring layer and the lower surface of the second wiring layer is a first distance. The metal film is formed on each of the plurality of wiring layers disposed on the peripheral region so as to be spaced apart from the third coil and the fourth coil by the first distance or more in cross-sectional view.

According to the semiconductor device of the present disclosure, it is possible to reduce the amount of warpage.

### BRIEF DESCRIPTION OF THE DRAWINGS

FIG. 1 is a block diagram of a semiconductor device DEV1.

FIG. 2 is an explanatory diagram illustrating an example of signal transmitting from a control circuit CC to a driving circuit DR.

FIG. 3 is a first plan view of a semiconductor chip CHP3.

FIG. 4 is a second plan view of the semiconductor chip CHP3.

FIG. 5 is a third plan view of the semiconductor chip CHP3.

FIG. 6 is a cross-sectional view taken along line VI-VI in FIG. 5.

FIG. 7 is a cross-sectional view taken along line VII-VII in FIG. 5.

FIG. 8 is a manufacturing process diagram of the semiconductor chip CHP3.

FIG. 9 is a cross-sectional view illustrating an interlayer insulating film formation step S2.

FIG. 10 is a cross-sectional view illustrating a contact plug formation step S3.

FIG. 11 is a cross-sectional view illustrating a wiring formation step S4.

FIG. 12 is a cross-sectional view illustrating an interlayer insulating film formation step S5.

FIG. 13 is a cross-sectional view illustrating a via plug formation step S6.

FIG. 14 is a cross-sectional view illustrating a wiring formation step S7.

FIG. 15 is a cross-sectional view illustrating a passivation film formation step S8.

FIG. 16 is a schematic graph illustrating the amount of wafer warpage in Sample 1 and Sample 2 as manufacturing process progresses.

FIG. 17 is a schematic graph illustrating the relationship between the number of wiring layers WL and the amount of wafer warpage.

FIG. 18 is a plan view of the semiconductor chip CHP3 included in a semiconductor device DEV2.

FIG. 19 is a cross-sectional view taken along line XIX-XIX in FIG. 18.

FIG. 20 is a first cross-sectional view taken along line XX-XX in FIG. 18.

FIG. 21 is a first cross-sectional view illustrating a dicing step S10 in the semiconductor chip CHP3 included in the semiconductor device DEV2.

FIG. 22 is a second cross-sectional view illustrating the dicing step S10 in the semiconductor chip CHP3 included in the semiconductor device DEV2.

FIG. 23 is a plan view of the semiconductor chip CHP3 included in a semiconductor device DEV3.

### DETAILED DESCRIPTION

Details of the embodiments of the present disclosure will be described with reference to the drawings. In the following drawings, the same or corresponding parts are given the same reference symbols, and duplicate descriptions will not be repeated.

### First Embodiment

A semiconductor device according to a first embodiment will be described. The semiconductor device according to the first embodiment is referred to as a semiconductor device DEV1.

### (Configuration of Semiconductor Device DEV1)

The following describes the configuration of the semiconductor device DEV1.

### <General Configuration of Semiconductor Device DEV1>

The following describes the general configuration of the semiconductor device DEV1.

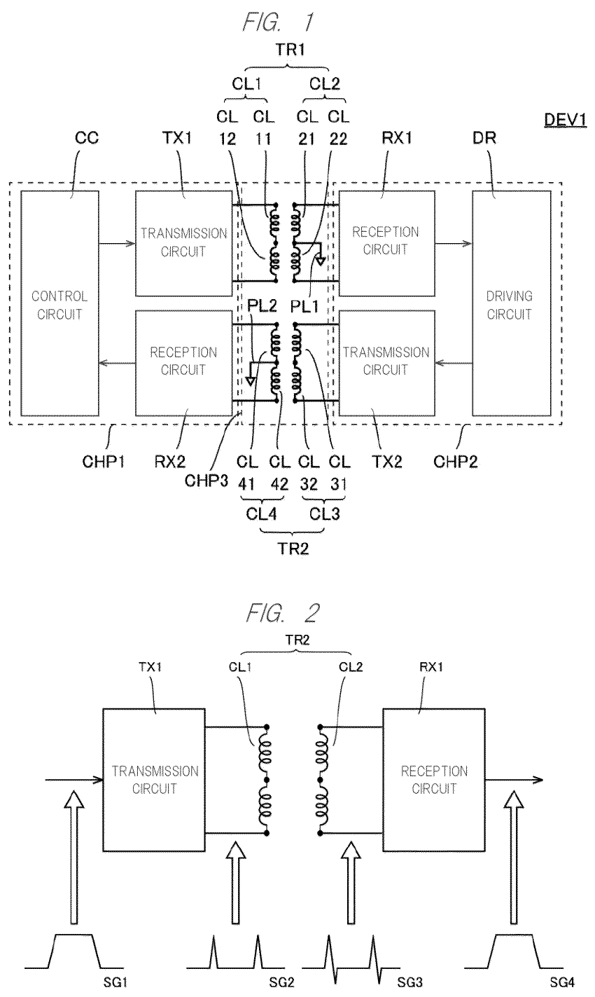

FIG. 1 is a block diagram of the semiconductor device DEV1. As illustrated in FIG. 1, the semiconductor device DEV1 includes a semiconductor chip CHP1, a semiconductor chip CHP2, and a semiconductor chip CHP3.

The semiconductor chip CHP1 includes a control circuit CC, a transmission circuit TX1, and a reception circuit RX2, and the semiconductor chip CHP2 includes a driving circuit DR, a reception circuit RX1, and a transmission circuit TX2. The transmission circuit TX1 and the reception circuit RX2 are electrically connected to the control circuit CC. The reception circuit RX1 and the transmission circuit TX2 are electrically connected to the driving circuit DR.

The semiconductor chip CHP3 includes a transformer TR1, a transformer TR2, and a lead-out wiring PL1 and a lead-out wiring PL2.

The transformer TR1 includes a transmission coil CL1 and a reception coil CL2. The transmission coil CL1 includes a coil CL11 and a coil CL12, and the reception coil CL2 includes a coil CL21 and a coil CL22. The transmission coil CL1 and the reception coil CL2 are electrically connected to the transmission circuit TX1 and the reception circuit RX1, respectively.

More specifically, one end of the coil CL11 is electrically connected to the transmission circuit TX1, another end of the coil CL11 is electrically connected to one end of the coil CL12, and another end of the coil CL12 is electrically connected to the transmission circuit TX1. One end of the coil CL21 is electrically connected to the reception circuit RX1, another end of the coil CL21 is electrically connected to one end of the coil CL22 via the lead-out wiring PL1, and another end of the coil CL22 is electrically connected to the reception circuit RX1.

The transformer TR2 includes a transmission coil CL3 and a reception coil CL4. The transmission coil CL3 includes a coil CL31 and a coil CL32, and the reception coil CL4 includes a coil CL41 and a coil CL42. The transmission coil CL3 and the reception coil CL4 are electrically connected to the transmission circuit TX2 and the reception circuit RX2, respectively.

More specifically, one end of the coil CL31 is electrically connected to the transmission circuit TX2, another end of the coil CL31 is electrically connected to one end of the coil CL32, and another end of the coil CL32 is electrically connected to the transmission circuit TX2. One end of the coil CL41 is electrically connected to the reception circuit RX2, another end of the coil CL41 is electrically connected to one end of the coil CL42 via the lead-out wiring PL2, and another end of the coil CL42 is electrically connected to the reception circuit RX2.

In the semiconductor device DEV1, a signal is transmitted from the control circuit CC to the driving circuit DR by the transmission circuit TX1, the transformer TR1, and the reception circuit RX1. Also, in the semiconductor device DEV1, a signal is transmitted from the driving circuit DR to the control circuit CC by the transmission circuit TX2, the transformer TR2, and the reception circuit RX2.

FIG. 2 is an explanatory diagram illustrating an example of signal transmitting from the control circuit CC to the driving circuit DR. As illustrated in FIG. 2, the control circuit CC inputs a signal SG1 to the transmission circuit TX1. The signal SG1 is a square wave. The transmission circuit TX1 modulates the signal SG1 into a signal SG2 and sends the signal SG2 to the transmission coil CL1. When the signal SG2 flows through the transmission coil CL1, a signal SG3 corresponding to the signal SG2 flows through the reception coil CL2 due to an induced electromotive force. The reception circuit RX1 amplifies the signal SG3 and demodulates it to a signal SG4 (a square wave), and then, outputs the SG4 to the driving circuit DR. Accordingly, the signal is transmitted from the control circuit CC to the driving circuit DR. Note that the transmission of signal from the driving circuit DR to the control circuit CC is performed in a similar manner. In this manner, in the semiconductor device DEV1, signal transmission between the transmission circuit TX1 and the reception circuit RX1, as well as signal transmission between the transmission circuit TX2 and the reception circuit RX2, is performed using a pulse communication system.

### <Detailed Configuration of Semiconductor Chip CHP3>

The following describes the detailed configuration of the semiconductor chip CHP3.

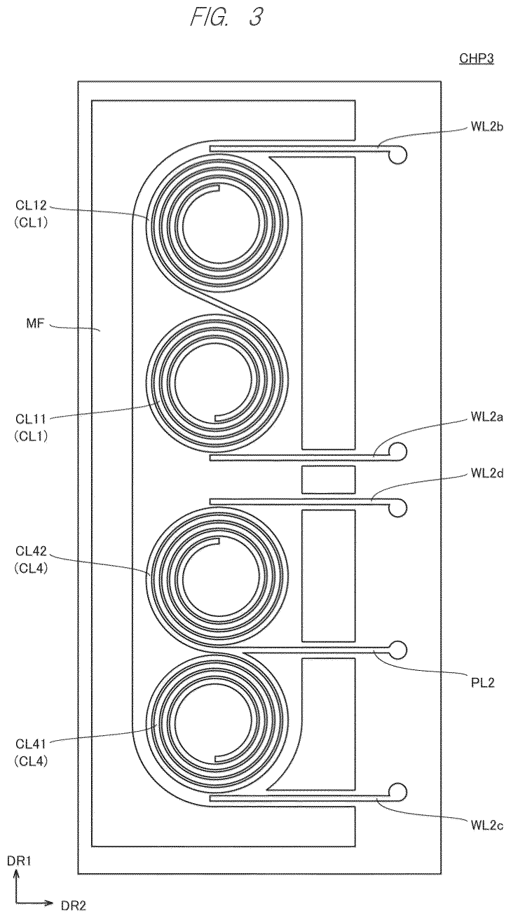

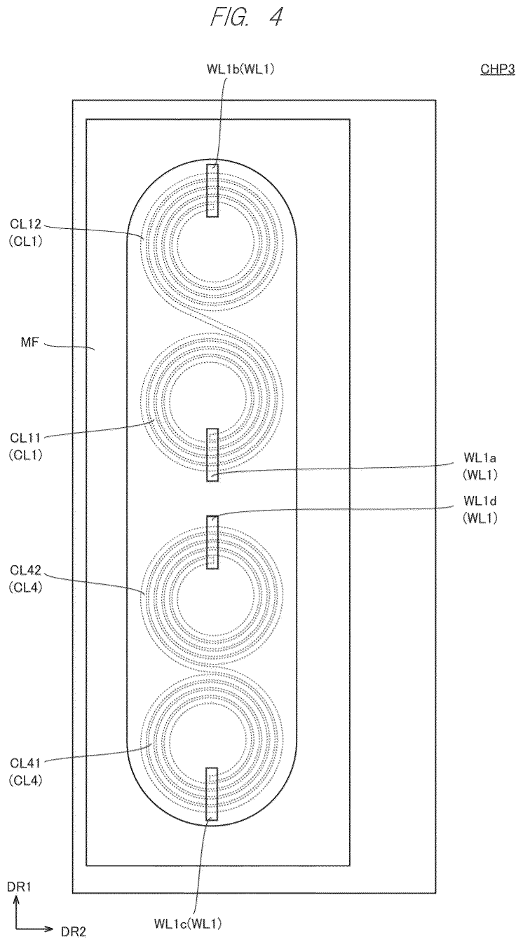

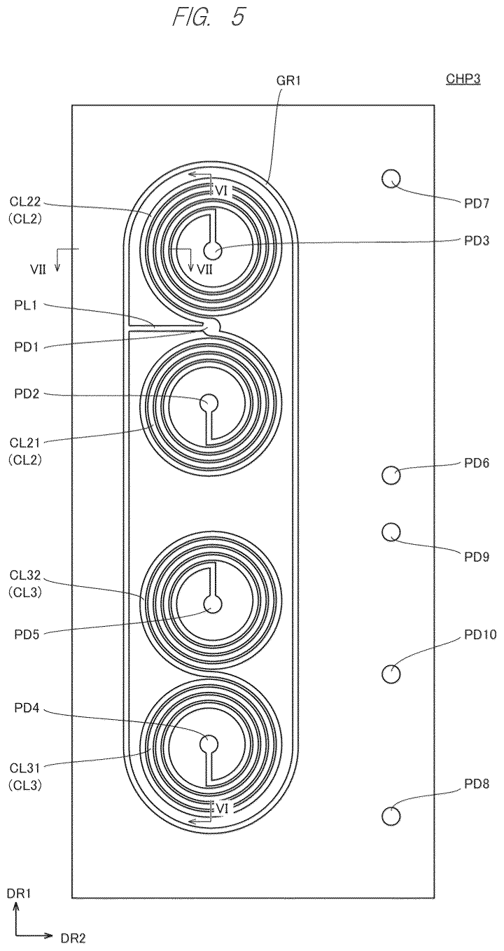

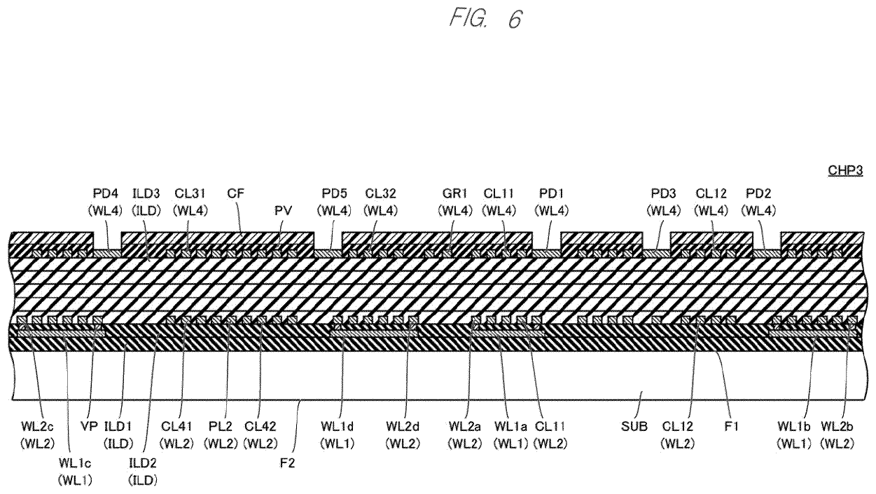

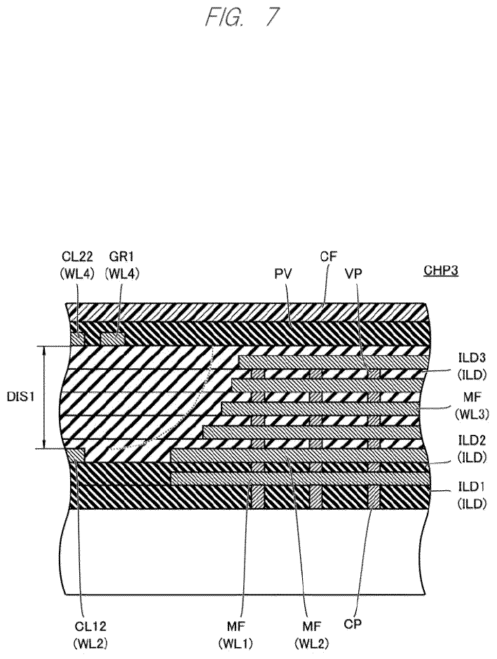

FIG. 3 is a first plan view of the semiconductor chip CHP3. FIG. 4 is a second plan view of the semiconductor chip CHP3. FIG. 5 is a third plan view of the semiconductor chip CHP3. FIG. 6 is a cross-sectional view taken along line VI-VI in FIG. 5. FIG. 7 is a cross-sectional view taken along line VII-VII in FIG. 5. As illustrated in FIGS. 3 to 7, the semiconductor chip CHP3 includes a semiconductor substrate SUB, a multilayer wiring layer, a passivation film PV, and a cover film CF.

The semiconductor substrate SUB includes a first face F1 and a second face F2. The first face F1 and the second face F2 are end faces in the thickness direction of the semiconductor substrate SUB. The second face F2 is the opposite surface to the first face F1. A constituent material of the semiconductor substrate SUB is, for example, single crystal silicon. The semiconductor substrate SUB has a coil region and a peripheral region in plan view. The peripheral region surrounds the coil region in plan view.

The multilayer wiring layer includes a plurality of interlayer insulating films ILD and a plurality of wiring layers WL. A constituent material of the interlayer insulating film ILD is, for example, silicon oxide. A main component of the constituent material of the wiring layer WL is, for example, aluminum. The main component of the constituent material of the wiring layer WL being aluminum means that the aluminum content in the constituent material of the wiring layer WL is 50 mass percent or more.

The lowermost interlayer insulating film ILD is referred to as an interlayer insulating film ILD1. The interlayer insulating film ILD on the interlayer insulating film ILD1 is referred to as an interlayer insulating film ILD2. Each of the interlayer insulating films ILD disposed on the interlayer insulating film ILD2 is referred to as an interlayer insulating film ILD3. The wiring layer WL disposed on the interlayer insulating film ILD1 is referred to as a wiring layer WL1. The wiring layer WL disposed on the interlayer insulating film ILD2 is referred to as a wiring layer WL2. The wiring layers WL disposed on the interlayer insulating films ILD3 are referred to as wiring layers WL3. However, the wiring layer WL disposed on the uppermost interlayer insulating film ILD3 is referred to as a wiring layer WL4.

The wiring layer WL2 includes the transmission coil CL1 (coil CL11, coil CL12), the reception coil CL4 (coil CL41, coil CL42), and the lead-out wiring PL2. The wiring layer WL2 further includes a wiring WL2a, a wiring WL2b, a wiring WL2c, and a wiring WL2d. The transmission coil CL1 and the reception coil CL4 are disposed on the coil region of the semiconductor substrate SUB. The transmission coil CL1 and the reception coil CL4 are aligned along a first direction DR1 in plan view.

The coil CL11 and the coil CL12 are aligned along the first direction DR1 in plan view. The coil CL11 and the coil CL12 are wound in a spiral shape in plan view. The coil CL11 is wound counterclockwise from the innermost circumference toward the outermost circumference. The coil CL12 is wound clockwise from the outermost circumference toward the innermost circumference. An outermost end of the coil CL11 is connected to an outermost end of the coil CL12. From another perspective, the coil CL11 and the coil CL12 are configured in a serial aiding configuration.

The coil CL41 and the coil CL42 are aligned along the first direction DR1 in plan view. The coil CL41 and the coil CL42 are wound in a spiral shape in plan view. The coil CL41 is wound counterclockwise from the innermost circumference toward the outermost circumference. The coil CL42 is wound clockwise from the outermost circumference toward the innermost circumference. An outermost end of the coil CL41 is connected to an outermost end of the coil CL42 via one end of the lead-out wiring PL2. From another perspective, the coil CL41 and the coil CL42 are configured in a serial aiding configuration.

The lead-out wiring PL2 extends along a second direction DR2. The second direction DR2 is perpendicular to the first direction DR1.

The wiring WL2a, the wiring WL2b, the wiring WL2c, and the wiring WL2d extend along the second direction DR2 in plan view. One end of the wiring WL2a in the second direction DR2 and one end of the wiring WL2b in the second direction DR2 are adjacent to the coil CL11 and the coil CL12, respectively. One end of the wiring WL2c in the second direction DR2 and one end of the wiring

WL2d in the second direction DR2 are adjacent to the coil CL41 and the coil CL42, respectively.

The wiring layer WL1 further includes a wiring WL1a, a wiring WL1b, a wiring WL1c, and a wiring WL1d. The wiring WL1a, the wiring WL1b, the wiring WL1c, and the wiring WL1d extend along the first direction DR1 in plan view.

One end and another end of the wiring WL1a in the first direction DR1 overlap the one end of the wiring WL2a and an innermost end of the coil CL11, respectively. One end and another end of the wiring WL1b in the first direction DR1 overlap the one end of the wiring WL2b and an innermost end of the coil CL12, respectively. One end and another end of the wiring WL1c in the first direction DR1 overlap the one end of the wiring WL2c and an innermost end of the coil CL41, respectively. One end and another end of the wiring WL1d in the first direction DR1 overlap the one end of the wiring WL2d and an innermost end of the coil CL42, respectively.

The one end and the other end of the wire WL1a in the first direction DR1 are electrically connected to the one end of the wire WL2a and the innermost end of the coil CL11 by via plugs VP, respectively. The one end and the other end of the wire WL1b in the first direction DR1 are electrically connected to the one end of the wire WL2b and the innermost end of the coil CL12 by via plugs VP, respectively. The one end and the other end of the wire WL1c in the first direction DR1 are electrically connected to the one end of the wire WL2c and the innermost end of the coil CL41 by via plugs VP, respectively. The one end and the other end of the wire WL1d in the first direction DR1 are electrically connected to the one end of the wire WL2d and the innermost end of the coil CL42 by via plugs VP, respectively. The via plug VP is embedded in a via hole formed in the interlayer insulating film ILD. A constituent material of the via plug VP is, for example, tungsten.

The wiring layer WL4 includes the reception coil CL2 (coil CL21, coil CL22), the transmission coil CL3 (coil CL31, coil CL32). The wiring layer WL4 further includes a pad PD1, a pad PD2, a pad PD3, a pad PD4, a pad PD5, a pad PD6, a pad PD7, a pad PD8, a pad PD9, and a pad PD10. The wiring layer WL4 further includes a guard ring GR1 and the lead-out wiring PL1.

The reception coil CL2 and the transmission coil CL3 are aligned along the first direction DR1 in plan view. The reception coil CL2 and the transmission coil CL3 overlap the transmission coil CL1 and the reception coil CL4 in plan view, respectively. That is, the coil CL21 and the coil CL22 face the coil CL11 and the coil CL12, respectively, with the insulating layer (a plurality of interlayer insulating films ILD3) therebetween, and the coil CL31 and the coil CL32 face the coil CL41 and the coil CL42, respectively, with the insulating layer (the plurality of interlayer insulating films ILD3) therebetween. From another perspective, the coil CL21 and the coil CL22 are magnetically coupled to the coil CL11 and the coil CL12, respectively, and the coil CL31 and the coil CL32 are magnetically coupled to the coil CL41 and the coil CL42, respectively.

The distance between the lower surface of the wiring layer WL4 and the upper surface of the wiring layer WL2 is referred to as the distance DIS1. The distance DIS1 corresponds to the distance between the transmission coil CL1 and the reception coil CL2, as well as the distance between the transmission coil CL3 and the reception coil CL4. The distance DIS1 is, for example, 5 μm or more and 20 μm or less.

The coil CL21 and the coil CL22 are aligned along the first direction DR1 in plan view. The coil CL21 and the coil CL22 are wound in a spiral shape in plan view. The coil CL21 is wound counterclockwise from the innermost circumference toward the outermost circumference. The coil CL22 is wound clockwise from the outermost circumference toward the innermost circumference. An outermost end of the coil CL21 is connected to an outermost end of the coil CL22 via the pad PD1. From another perspective, the coil CL21 and the coil CL22 are configured in a serial aiding configuration.

The coil CL31 and the coil CL32 are aligned along the first direction DR1 in plan view. The coil CL31 and the coil CL32 are wound in a spiral shape in plan view. The coil CL31 is wound counterclockwise from the innermost circumference toward the outermost circumference. The coil CL32 is wound clockwise from the outermost circumference toward the innermost circumference. An outermost end of the coil CL31 is connected to an outermost end of the coil CL32. From another perspective, the coil CL31 and the coil CL32 are configured in a serial aiding configuration.

The pad PD2 and the pad PD3 are connected to an innermost end of the coil CL21 and an innermost end of the coil CL22, respectively. The pad PD4 and the pad PD5 are connected to an innermost end of the coil CL31 and an innermost end of the coil CL32, respectively.

The pad PD6, the pad PD7, the pad PD8, the pad PD9, and the pad PD10 are disposed on the peripheral region of the semiconductor substrate SUB. The pad PD6, the pad PD7, the pad PD8, the pad PD9, and the pad PD10 are aligned along the first direction DR1 in plan view. The pad PD6 and the pad PD7 overlap another end of the wiring WL2a and another end of the wiring WL2b in plan view. The pad PD8 and the pad PD9 overlap another end of the wiring WL2c and another end of the wiring WL2d in plan view. The pad PD10 overlaps another end of the lead-out wiring PL2 in plan view.

Although not illustrated, the pad PD6, the pad PD7, the pad PD8, the pad PD9, and the pad PD10 are electrically connected to the other end of the wiring WL2a, the other end of the wiring WL2b, the other end of the wiring WL2c, the other end of the wiring WL2d and another end of pull-out wiring PL2, respectively, by via plugs VP and the plurality of wiring layers WL3.

The guard ring GR1 surrounds the reception coil CL2 and the transmission coil CL3 in plan view. The lead-out wiring PL1 extends along the first direction DR1 in plan view. The lead-out wiring PL1 has one end connected to the pad PD1 and another end connected to the guard ring GR1. A reference potential is applied to the pad PD1. Therefore, the same reference potential is applied to the guard ring GR1. It should be noted that a higher reference potential is applied to pad PD10 than to pad PD1.

The multilayer wiring layer further includes a plurality of metal films MF. The plurality of metal films MF is disposed on the peripheral region of the semiconductor substrate SUB. More specifically, each of the wiring layer WL1, the wiring layer WL2 and the plurality of wiring layers WL3 has a metal film MF. Each of the plurality of metal films MF is spaced apart from the reception coil CL2 (coil CL21, coil CL22) by the distance DIS1 or more. From another perspective, each of the plurality of metal films MF is not disposed inside the arc indicated by the dotted line in FIG. 7, and the metal films MF in the upper layers have a smaller occupied area. Although not illustrated, each of the plurality of metal films MF is also spaced apart from the transmission coil CL3 (coil CL31, coil CL32) by the distance DIS1 or more. Adjacent metal films MF are connected to each other by the via plugs VP, and the metal film MF (the lowermost metal film MF) formed in the wiring layer WL1 is connected to the semiconductor substrate SUB by contact plugs CP. A contact plug CP is embedded in a contact hole formed in the interlayer insulating film ILD1.

The passivation film PV is disposed on the uppermost interlayer insulating film ILD3 so as to cover the wiring layer WL4. Openings are formed in the passivation film PV. From the openings in the passivation film PV, the pad PD1, the pad PD2, the pad PD3, the pad PD4, the pad PD5, the pad PD6, the pad PD7, the pad PD8, the pad PD9, and the pad PD10 are exposed. The constituent material of the passivation film PV is, for example, silicon nitride.

The cover film CF is disposed on the passivation film PV. A constituent material of the cover film CF is, for example, polyimide.

### <Manufacturing Method of Semiconductor Chip CHP3>

The following describes a method of manufacturing the semiconductor chip CHP3.

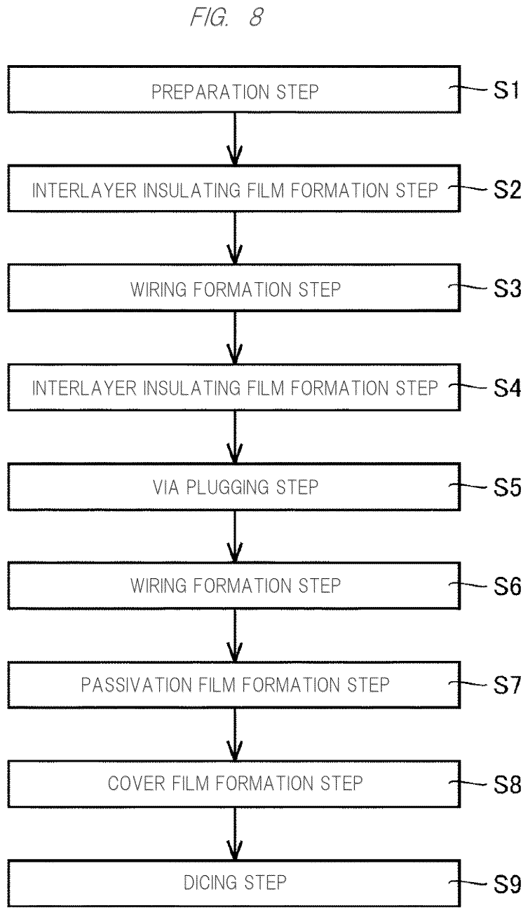

FIG. 8 is a manufacturing process diagram of the semiconductor chip CHP3. As illustrated in FIG. 8, the method of manufacturing the semiconductor chip CHP3 includes a preparation step S1, an interlayer insulating film formation step S2, a contact plug formation step S3, a wiring formation step S4, an interlayer insulating film formation step S5, a via plug formation step S6, a wiring formation step S7, a passivation film formation step S8, a cover film formation step S9, and a dicing step S10.

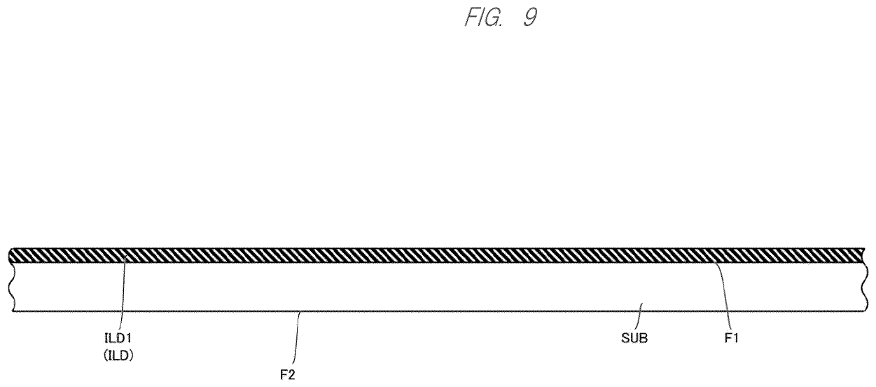

In the preparation step S1, a semiconductor substrate SUB is prepared. FIG. 9 is a cross-sectional view illustrating the interlayer insulating film formation step S2. As illustrated in FIG. 9, in the interlayer insulating film formation step S2, an interlayer insulating film ILD, more specifically, an interlayer insulating film ILD1 is formed. The interlayer insulating film ILD1 is formed by depositing the constituent material of the interlayer insulating film ILD1 on the semiconductor substrate SUB by, for example, a Chemical Vapor Deposition (CVD) method, and then planarizing the deposited constituent material of the interlayer insulating film ILD1 by a Chemical Mechanical Polishing (CMP) method.

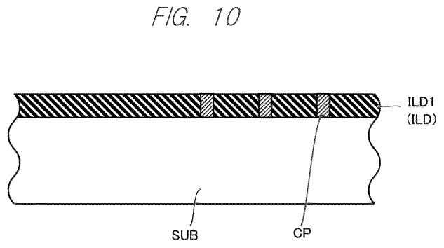

FIG. 10 is a cross-sectional view illustrating the contact plug formation step S3. As illustrated in FIG. 10, the contact plug CP is formed. In the contact plug formation step S3, first, a contact hole is formed in the interlayer insulating film ILD1. The contact hole is formed by disposing a resist pattern on the interlayer insulating film ILD1 and etching the interlayer insulating film ILD1 using the resist pattern as a mask. The resist pattern is formed by disposing a photoresist on the interlayer insulating film ILD1 and patterning the photoresist by photolithography. Secondly, a constituent material of the contact plug CP is embedded in the contact hole by, for example, the CVD method. Thirdly, the constituent material of the contact plug CP that protrudes from the contact hole is removed by, for example, the CMP method. In this manner, the contact plug CP is formed.

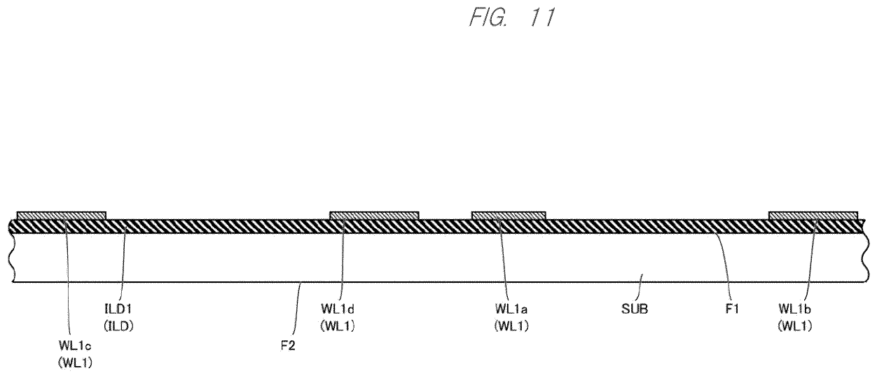

FIG. 11 is a cross-sectional view illustrating the wiring formation step S4. As illustrated in FIG. 11, in the wiring formation step S4, the wiring layer WL, more specifically, the wiring layer WL1 is formed. In the wiring formation step S4, first, the constituent material of the wiring layer WL1 is deposited on the interlayer insulating film ILD1 by, for example, sputtering. Secondly, a resist pattern is formed on the constituent material of the deposited wiring layer WL1. The resist pattern is formed by disposing a photoresist on the constituent material of the deposited wiring layer WL1 and patterning the photoresist by photolithography. Thirdly, the constituent material of the wiring layer WL1 that has been deposited is etched using the resist pattern as a mask. In this manner, the wiring layer WL1 is formed. After the wiring layer WL1 is formed, the resist pattern is removed.

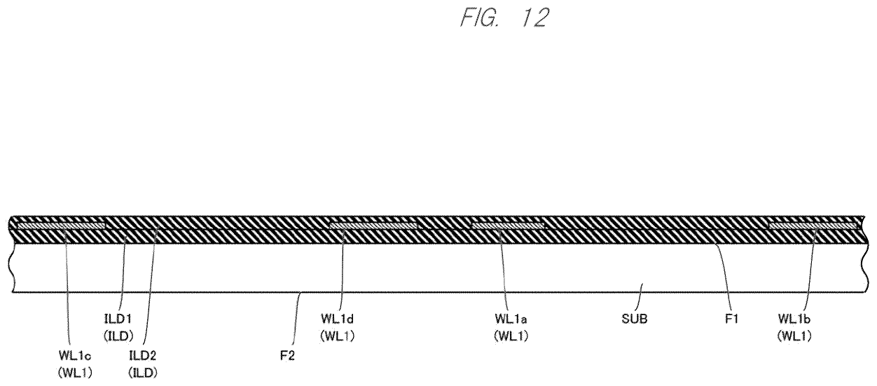

FIG. 12 is a cross-sectional view illustrating the interlayer insulating film formation step S5. As illustrated in FIG. 12, in the interlayer insulating film formation step S5, an interlayer insulating film ILD, more specifically, an interlayer insulating film ILD2 is formed. The interlayer insulating film ILD2 is formed by depositing the constituent material of the interlayer insulating film ILD2 on the semiconductor substrate SUB, for example, by the CVD method, on the interlayer insulating film ILD1 so as to cover the wiring layer WL1, and then planarizing the deposited constituent material of the deposited interlayer insulating film ILD2 by the CMP method.

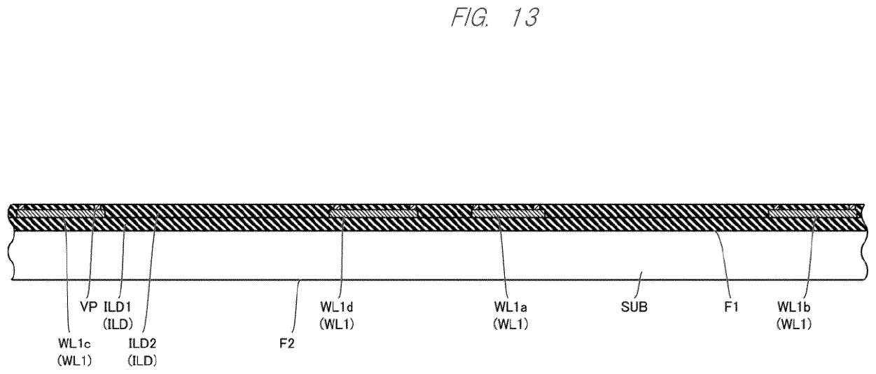

FIG. 13 is a cross-sectional view illustrating the via plug formation step S6. As illustrated in FIG. 13, in the via plug formation step S6, a via plug VP is formed. In the via plug formation step S6, first, a via hole is formed in the interlayer insulating film ILD2. The via hole is formed by disposing a resist pattern on the interlayer insulating film ILD2 and etching the interlayer insulating film ILD2 using the resist pattern as a mask. The resist pattern is formed by disposing a photoresist on the interlayer insulating film ILD2 and patterning the photoresist by photolithography. Secondly, the constituent material of the via plug VP is embedded in the via hole by, for example, the CVD method. Thirdly, the constituent material of the via plug VP that protrudes from the via hole is removed by, for example, the CMP method. In this manner, the via plug VP is formed.

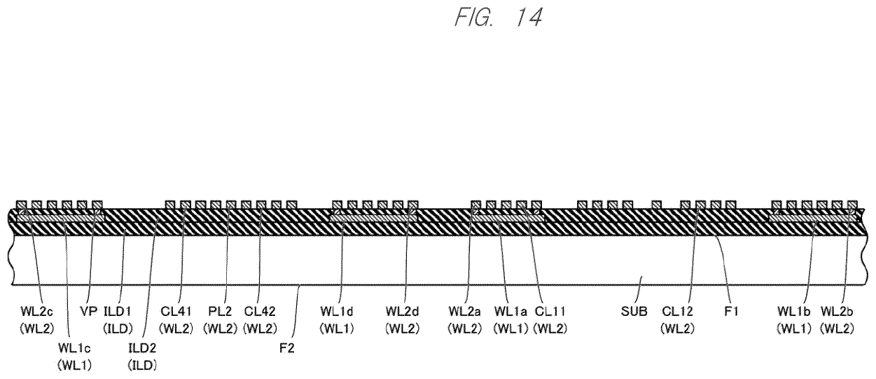

FIG. 14 is a cross-sectional view illustrating a wiring formation step S7. As illustrated in FIG. 14, in the wiring formation step S7, the wiring layer WL2 is formed on the interlayer insulating film ILD2 in the same manner as in the wiring formation step S4. Thereafter, the interlayer insulating film formation step S5, the via plug formation step S6, and the wiring formation step S7 are repeatedly performed, thereby forming the plurality of interlayer insulating films ILD3 and the plurality of wiring layers WL3 and the wiring layer WL4.

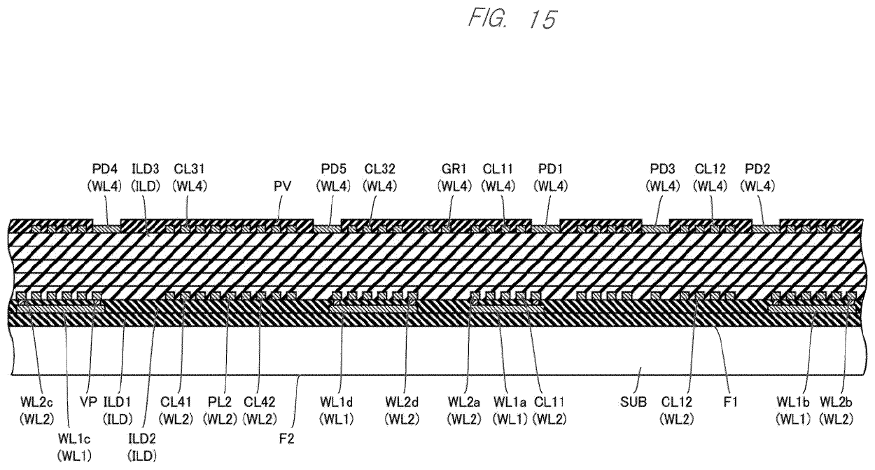

FIG. 15 is a cross-sectional view illustrating a passivation film formation step S8. In the passivation film formation step S8, a passivation film PV is formed. In the passivation film formation step S8, first, a constituent material of the passivation film PV is deposited on the uppermost interlayer insulating film ILD3 so as to cover the wiring layer WL4 by, for example, a CVD method. Secondly, a resist pattern is disposed on the deposited constituent material of the passivation film PV, and the constituent material of the passivation film PV is etched using the resist pattern as a mask. The resist pattern is formed by disposing a photoresist on the constituent material of the deposited passivation film PV and patterning the photoresist by photolithography. In this manner, the passivation film PV is formed.

In the cover film formation step S9, the cover film CF is formed on the passivation film PV. In the dicing step S10, the semiconductor substrate SUB, the multilayer wiring layer, the passivation film PV, and the cover film CF are cut along the scribe lanes to obtain the plurality of semiconductor chips CHP3.

### <Effect of Semiconductor Chip CHP3>

The following describes an effect of the semiconductor chip CHP3.

FIG. 16 is a schematic graph illustrating the amount of wafer warpage in Sample 1 and Sample 2 as manufacturing process progresses. Sample 1 is a sample in which the metal films MF are not formed. Sample 2 is a sample in which the metal films MF are formed. That is, Sample 1 does not correspond to the semiconductor chip CHP3, but Sample 2 corresponds to the semiconductor chip CHP3. As illustrated in FIG. 16, in Sample 1 and Sample 2, the amount of wafer warpage decreases as the number of formed wiring layer WL increases, but overall the amount of wafer warpage increases as the manufacturing process progresses.

The reduction in the amount of wafer warpage when the wiring layers WL are formed increases as an occupied area by the wiring layer WL increases. In Sample 2, the wiring layers WL (wiring layer WL1, wiring layer WL2, and wiring layer WL3) each have the metal film MF, so that the occupied area by the wiring layers WL is larger than that of Sample 1. As a result, in Sample 2, the reduction in the amount of wafer warpage when the wiring layers WL are formed is greater than in Sample 1, and therefore the amount of wafer warpage is reduced when viewed as a whole wafer.

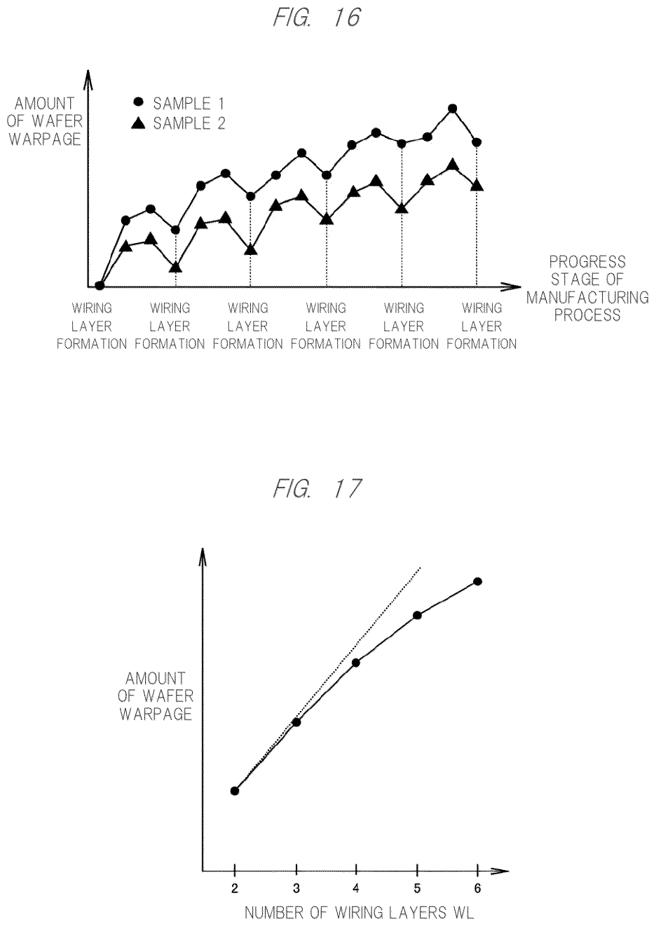

In the semiconductor chip CHP3, the higher the metal film MF is positioned, the smaller its occupied area becomes. FIG. 17 is a schematic graph illustrating the relationship between the number of wiring layers WL and the amount of wafer warpage. As illustrated in FIG. 17, the higher the wiring layer WL is positioned, the smaller the wafer warpage per wiring layer WL1 becomes. Therefore, even if the occupied area of the metal film MF in the upper layer is smaller than that of the metal film MF in the lower layer, the effect of suppressing the amount of wafer warpage is not significantly reduced.

Further, in the semiconductor chip CHP3, the metal films MF are spaced apart from the reception coil CL2 (transmission coil CL3) by the distance DIS1 or more. Therefore, even if the multilayer wiring layer includes the metal films MF, the dielectric breakdown voltage does not decrease compared to the case where the multilayer wiring layer does not include the metal films MF. Accordingly, the semiconductor chip CHP3 can reduce the amount of warpage while maintaining the dielectric breakdown voltage.

As a method of connecting the guard ring GR1 and the reception coil CL2, it is conceivable to arrange the pad PD1 in contact with the guard ring GR1, connect one end of the lead wiring PL1 to the pad PD1, and connect the coil CL11 and the coil CL12 via another end of the lead wiring PL1. In the semiconductor chip CHP3, the coil CL11 and the coil CL12 are connected via the pad PD1. As a result, the pad PD1 is positioned inside the guard ring GR1, leading to an improvement in the dielectric breakdown voltage.

### Second Embodiment

A semiconductor device according to a second embodiment will be described. The semiconductor device according to the second embodiment is referred to as a semiconductor device DEV2. Here, differences from the semiconductor device DEV2 will be mainly described, and redundant descriptions will not be repeated.

### <Configuration of Semiconductor Device DEV2>

The following describes the configuration of the semiconductor device DEV2.

The semiconductor device DEV2 includes a semiconductor chip CHP1, a semiconductor chip CHP2, and a semiconductor chip CHP3. In the semiconductor device DEV2, the semiconductor chip CHP3 includes a semiconductor substrate SUB, a multilayer wiring layer (a plurality of wiring layers WL, a plurality of interlayer insulating films ILD), a passivation film PV, and a cover film CF. The configuration of the semiconductor device DEV2 is similar to the configuration of the semiconductor device DEV2 in this regard. In the semiconductor device DEV2, the multilayer wiring layer may or may not include a plurality of metal films MF.

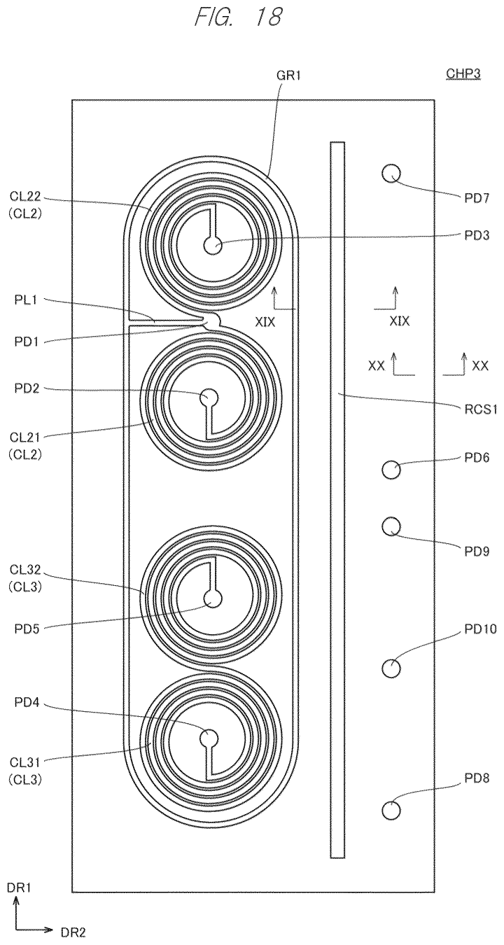

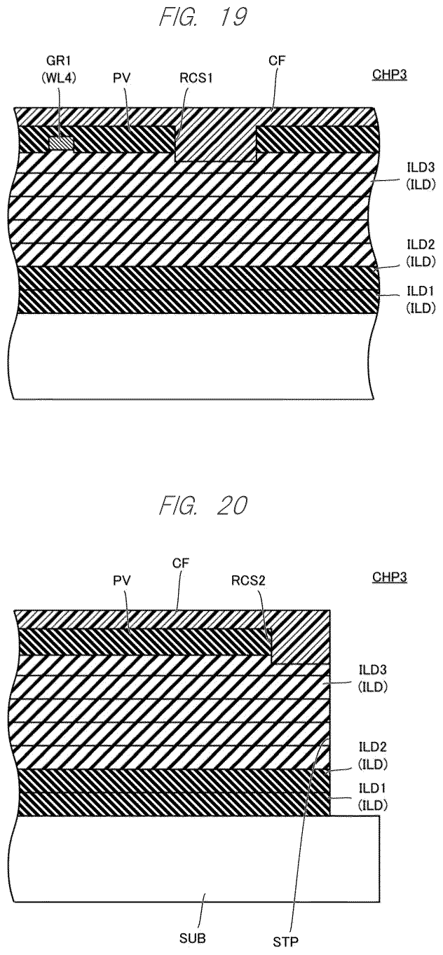

FIG. 18 is a plan view of the semiconductor chip CHP3 included in the semiconductor device DEV2. FIG. 19 is a cross-sectional view taken along line XIX-XIX in FIG. 18. As illustrated in FIG. 18 and FIG. 19, in the semiconductor device DEV2, a recess RCS1 is formed in the passivation film PV. The recess RCS1 extends along the first direction DR1 in plan view. A row of a pad PD6, a pad PD7, a pad PD8, a pad PD9, and a pad PD10 is referred to as a pad row. The recess RCS1 is disposed between the guard ring GR1 and the pad row in the second direction DR2.

In the example illustrated in FIG. 18 and FIG. 19, one recess RCS1 is formed, but a plurality of recesses RCS1 may be arranged in the second direction DR2. That is, a plurality of recesses RCS1 may be formed in a stripe pattern. The recess RCS1 may not extend along the first direction DR1. For example, the plurality of recesses RCS1 may be formed in a dot pattern or a staggered pattern in plan view.

The recess RCS1, for example, extends through the passivation film PV. The bottom of the recess RCS1 may reach below the upper surface of the uppermost interlayer insulating film ILD3. The cover film CF is disposed not only on the passivation film PV but also in the recess RCS1. The configuration of the semiconductor device DEV2 is different from the configuration of the semiconductor device DEV1 in this regard.

### <Manufacturing Method of Semiconductor Chip CHP3>

A method of manufacturing the semiconductor chip CHP3 included in the semiconductor device DEV2 will be described below.

The method of manufacturing the semiconductor chip CHP3 included in the semiconductor device DEV2 includes a preparation step S1, an interlayer insulating film formation step S2, a contact plug formation step S3, a wiring formation step S4, an interlayer insulating film formation step S5, a via plug formation step S6, a wiring formation step S7, a passivation film formation step S8, a cover film formation step S9, and a dicing step S10. The method of manufacturing the semiconductor chip CHP3 included in the semiconductor device DEV2 is similar to the method of manufacturing the semiconductor chip CHP3 included in the semiconductor device DEV1 in this regard.

In the passivation film formation step S8 of the method of manufacturing the semiconductor chip CHP3 included in the semiconductor device DEV2, the recess RCS1 is formed when an opening is formed in the passivation film PV. The method of manufacturing the semiconductor chip CHP3 included in the semiconductor device DEV2 is different from the method of manufacturing the semiconductor chip CHP3 included in the semiconductor device DEV1 in this regard.

### <Effect of Semiconductor Chip CHP3>

The following describes an effect of the semiconductor chip CHP3 included in the semiconductor device DEV2.

In the semiconductor chip CHP3 included in the semiconductor device DEV2, the recess RCS1 is formed. As a result, the creepage distance between the guard ring GR1 and the pad row becomes large. Therefore, according to the semiconductor chip CHP3 included in the semiconductor device DEV2, the creepage breakdown voltage between the guard ring GR1 and the pad row is improved. In addition, since the recess RCS1 can be formed in the passivation film formation step S8, it is not necessary to introduce a new step for forming the recess RCS1.

### MODIFICATION

FIG. 20 is a cross-sectional view taken along line XX-XX In the semiconductor chip CHP3 included in the in FIG. 18. semiconductor device DEV2, a recess RCS2 may further be formed, as illustrated in FIG. 20. The recess RCS2 is formed in the outer periphery portion of the passivation film PV in plan view. The recess RCS2 may reach the outer periphery edge of the semiconductor chip CHP3 in plan view. The recess RCS2 extends through the passivation film PV and reaches a position below the upper surface of the uppermost interlayer insulating film ILD3. This leads to a configuration in which the corners of the semiconductor chip CHP3 are cut (removed), making it possible to suppress chipping (chip breakage) during dicing. Furthermore, this increases the creepage distance between the wiring layer WL4 and the outer periphery edge of the semiconductor chip CHP3, improving the dielectric breakdown voltage between the wiring layer WL4 and the outer periphery edge of the semiconductor chip CHP3.

In the semiconductor chip CHP3 included in the semiconductor device DEV2, a step STP may further be formed. The step STP is located outside the recess RCS2 in plan view and reaches the outer periphery edge of the semiconductor chip CHP3. The step STP extends through the multilayer wiring layer, and the semiconductor substrate SUB is exposed from the step STP.

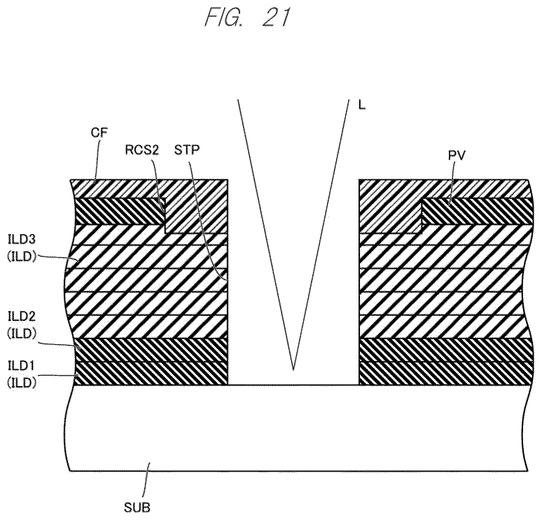

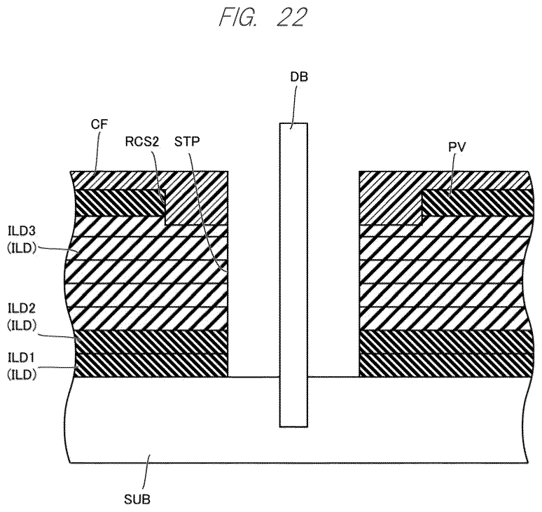

FIG. 21 is a first cross-sectional view illustrating the dicing step S10 in the semiconductor chip CHP3 included in the semiconductor device DEV2. As illustrated in FIG. 21, the step STP is formed by, for example, irradiating laser light L to remove the multilayer wiring layer. FIG. 22 is a second cross-sectional view illustrating the dicing step S10 in the semiconductor chip CHP3 included in the semiconductor device DEV2. As illustrated in FIG. 22, after the step STP is formed, the semiconductor substrate SUB is cut along the step STP using a dicing blade DB.

In this case, since the recess RCS2 and the step STP are formed, even if a seal ring is not formed in the multilayer wiring layer, a crack is unlikely to propagate through the multilayer wiring layer when cutting is performed with the dicing blade DB. In the above example, two-stage dicing is performed using the laser light L and the dicing blade DB, but the combination is not limited to the laser light L and the dicing blade DB as long as two-stage dicing is performed.

### Third Embodiment

A semiconductor device according to a third embodiment will be described. The semiconductor device according to the third embodiment is referred to as a semiconductor device DEV3. Here, differences from the semiconductor device DEV3 will be mainly described, and redundant descriptions will not be repeated.

### <Configuration of Semiconductor Device DEV3>

The following describes the configuration of the semiconductor device DEV3.

The semiconductor device DEV3 includes a semiconductor chip CHP1, a semiconductor chip CHP2, and a semiconductor chip CHP3. In the semiconductor device DEV3, the semiconductor chip CHP3 includes a semiconductor substrate SUB, a multilayer wiring layer (a plurality of wiring layers WL, a plurality of interlayer insulating films ILD), a passivation film PV, and a cover film CF. The configuration of the semiconductor device DEV3 is similar to the configuration of the semiconductor device DEV2 in this regard.

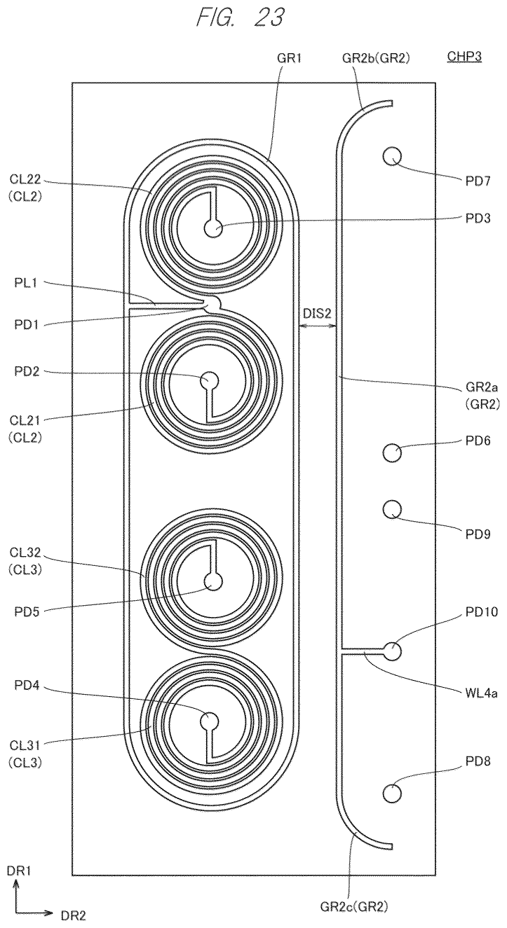

FIG. 23 is a plan view of the semiconductor chip CHP3 included in the semiconductor device DEV3. As illustrated in FIG. 23, in the semiconductor chip CHP3 included in the semiconductor device DEV3, a wiring layer WL4 has a guard ring GR2 and a wiring WL4a.

The guard ring GR2 has a central portion GR2a and an end portion GR2b and an end portion GR2c. The central portion GR2a extends along the first direction DR1 in plan view. The central portion GR2a is disposed between the pad row and the guard ring GR1 in the second direction DR2. The end portion GR2b and the end portion GR2c are connected to one end portion and another end portion of the central portion GR2a in the first direction DR1, respectively.

The end portion GR2b is curved so as to move away from the reception coil CL2 and the transmission coil CL3 in the second direction DR2 as it approaches the outer periphery edge of the semiconductor substrate SUB in the first direction DR1. The end portion GR2c is curved so as to move away from the reception coil CL2 and the transmission coil CL3 in the second direction DR2 as it approaches the outer periphery edge of the semiconductor substrate SUB in the first direction DR1. From another perspective, the guard ring GR2 is disposed so as to shield the pad row from the guard ring GR1, but does not surround the pad row on the side opposite to the guard ring GR2.

The distance DIS2 is defined as the shortest distance between the guard ring GR1 and the guard ring GR2. The distance DIS2 is, for example, 50 μm or more and 150 μm or less. The wiring WL4a has one end connected to the guard ring GR2 and another end connected to the pad PD10. Since the reference potential is applied to the pad PD10 as described above, the same reference potential as that of the pad PD10 is also applied to the guard ring GR2.

In the semiconductor device DEV3, the multilayer wiring layer may or may not include a plurality of metal films MF. Furthermore, in the semiconductor device DEV3, the recess RCS1, the recess RCS2 and the step STP may or may not be formed.

### <Effect of Semiconductor Chip CHP3 Included in Semiconductor Device DEV3>

The following describes an effect of the semiconductor chip CHP3 included in the semiconductor device DEV3.

In the semiconductor chip CHP3 of the semiconductor device DEV3, the guard ring GR2 is disposed between the guard ring GR1 and the pad row, and different reference potentials are applied to the guard ring GR1 and the guard ring GR2, thereby improving the dielectric breakdown voltage between the guard ring GR1 and the pad row. In addition, since the guard ring GR2 has the curbed end portion GR2b and end portion GR2c that extend away from the reception coil CL2 and the transmission coil CL3, a singular point is less likely to occur between the guard ring GR1 and the guard ring GR2, further improving the dielectric breakdown voltage between the guard ring GR1 and the pad row.

### APPENDIX

The above embodiments include the following configurations.

### Appendix 1

A semiconductor device comprising:
a first semiconductor chip;
a second semiconductor chip; and
a third semiconductor chip;
wherein the first semiconductor chip includes a first transceiver circuit,
wherein the second semiconductor chip includes a second transceiver circuit,
wherein the third semiconductor chip includes a semiconductor substrate and a multilayer wiring layer disposed on the semiconductor substrate,
wherein the multilayer wiring layer includes a first coil, a second coil, a third coil, a fourth coil, and a metal film,
wherein the semiconductor substrate includes, in plan view, a coil region and a peripheral region surrounding the coil region,
wherein the multilayer wiring layer includes a plurality of wiring layers,
wherein the first coil and the second coil are formed in a first wiring layer being one of the plurality of wiring layers disposed on the coil region,
wherein the third coil and the fourth coil are formed in a second wiring layer being another one of the plurality of wiring layers disposed on the coil region,
wherein the second wiring layer is disposed above the first wiring layer,
wherein the third coil and the fourth coil are disposed so as to face the first coil and the second coil, respectively,
wherein a distance between an upper surface of the first wiring layer and a lower surface of the second wiring layer is a first distance,
wherein the metal film is formed on each of the plurality of wiring layers disposed on the peripheral region so as to be spaced apart from the third coil and the fourth coil by the first distance or more in cross-sectional view.

The first transceiver circuit transmits a signal to and from the second transceiver circuit via the first coil, the second coil, the third coil, and the fourth coil.

### Appendix 2

The semiconductor device according to Appendix 1, wherein a signal transmission method between the first transceiver circuit and the second transceiver circuit is a pulse communication method.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

What is claimed is:

1. A semiconductor device comprising:
a semiconductor substrate; and
a multilayer wiring layer disposed on the semiconductor substrate,
wherein the multilayer wiring layer includes a first coil, a second coil, a third coil, a fourth coil, and a metal film,
wherein the semiconductor substrate includes, in plan view, a coil region and a peripheral region surrounding the coil region,
wherein the multilayer wiring layer includes a plurality of wiring layers,
wherein the first coil and the second coil are formed in a first wiring layer being one of the plurality of wiring layers disposed on the coil region,
wherein the third coil and the fourth coil are formed in a second wiring layer being another one of the plurality of wiring layers disposed on the coil region,
wherein the second wiring layer is disposed above the first wiring layer,
wherein the third coil and the fourth coil are disposed so as to face the first coil and the second coil, respectively,
wherein a distance between an upper surface of the first wiring layer and a lower surface of the second wiring layer is a first distance, and
wherein the metal film is formed on each of the plurality of wiring layers disposed on the peripheral region so as to be spaced apart from the third coil and the fourth coil by the first distance or more in cross-sectional view.

2. The semiconductor device according to claim 1,
wherein the second wiring layer is an uppermost layer of the plurality of wiring layers, and
wherein the metal film is formed on the first wiring layer and on each of the plurality of wiring layers located between the first wiring layer and the second wiring layer.

3. The semiconductor device according to claim 1,
wherein the first distance is 5 μm or more and 20 μm or less.

4. The semiconductor device according to claim 1,
wherein the first coil and the second coil overlap the third coil and the fourth coil, respectively.

5. The semiconductor device according to claim 1, further comprising:
a first lead-out wiring;
a first pad; and
a first guard ring,
wherein the second wiring layer is an uppermost layer of the plurality of wiring layers,
wherein the first lead-out wiring is formed in one of the plurality of wiring layers below the first wiring layer, and is electrically connected to the first coil,
wherein the first pad is formed in the second wiring layer disposed in the peripheral region and is electrically connected to the first lead-out wiring, and
wherein the first guard ring is disposed in the peripheral region to shield the third coil and the fourth coil from the first pad.

6. The semiconductor device according to claim 5,
wherein end portions of the first guard ring are curved so as to be spaced apart from the third coil and the fourth coil in plan view as the end portions approach a periphery of the peripheral region.

7. The semiconductor device according to claim 5,
wherein a side of the first pad close to the periphery in the peripheral region is not surrounded by the first guard ring.

8. The semiconductor device according to claim 5 further comprising
a passivation film disposed on an uppermost wiring layer of the plurality of wiring layers,
wherein a first recess is formed in the passivation film between the third coil and the fourth coil and the first guard ring in plan view in which the passivation film is at least partially removed, and
wherein the first recess extends in a same direction as the first guard ring.

9. The semiconductor device according to claim 8,
wherein the first recess is formed in plurality.

10. The semiconductor device according to claim 9,
wherein the first recesses are formed in a stripe pattern, a staggered pattern, or a dot pattern.

11. The semiconductor device according to claim 8,
wherein the multilayer wiring layer includes a plurality of interlayer insulating films, and
wherein the first recess extends through the passivation film, and is formed so that a bottom of the first recess is lower than an upper surface of a first interlayer insulating film being an uppermost layer of the plurality of interlayer insulating films.

12. The semiconductor device according to claim 1,
wherein the multilayer wiring layer includes a plurality of interlayer insulating films,
wherein a second recess is formed in the passivation film disposed on an outer periphery portion of the peripheral region, and
wherein the second recess extends through the passivation film, and is formed so that a bottom of the second recess is lower than an upper surface of a first interlayer insulating film being an uppermost layer of the multilayer wiring layer.

13. The semiconductor device according to claim 12,
wherein a step is formed on the outer periphery portion of the peripheral region extending through the multilayer wiring layer outside the second recess in a plan view, and
wherein the step is formed by a second dicing that is performed before a first dicing that cuts the semiconductor substrate.

14. The semiconductor device according to claim 5, further comprising
a second guard ring formed in the second wiring layer so as to surround the third coil and the fourth coil in plan view,
wherein a shortest distance between the first guard ring and the second guard ring is 50 μm or more and 150 μm or less.

15. The semiconductor device according to claim 14,
wherein a first reference potential and a second reference potential are applied to the first guard ring and the second guard ring, respectively, and
wherein the second reference potential is higher than the first reference potential.

16. The semiconductor device according to claim 14, further comprising
a second pad,
wherein the second pad is formed in the second wiring layer between the third coil and the fourth coil.

17. The semiconductor device according to claim 16,
wherein the second pad is electrically connected to the second guard ring.

18. The semiconductor device according to claim 1,
wherein the metal film is made of a material containing aluminum as a main component.

19. The semiconductor device according to claim 1,
wherein the first coil and the third coil are magnetically coupled to each other, and
wherein the second coil and the fourth coil are magnetically coupled to each other.

20. A semiconductor device comprising:
a semiconductor substrate; and
a multilayer wiring layer disposed on the semiconductor substrate,
wherein the multilayer wiring layer includes
a first coil, a second coil, a third coil, a fourth coil, a fifth coil, a sixth coil, a seventh coil, and an eighth coil, and
a metal film,
wherein the semiconductor substrate includes, in plan view, a coil region and a peripheral region surrounding the coil region,
wherein the multilayer wiring layer includes a plurality of wiring layers,
wherein the first coil, the second coil, the third coil, and the fourth coil are formed in a first wiring layer being one of the plurality of wiring layers disposed on the coil region,
wherein the fifth coil, the sixth coil, the seventh coil, and the eighth coil are formed in a second wiring layer being another one of the plurality of wiring layers disposed on the coil region,
wherein the second wiring layer is disposed above the first wiring layer,
wherein the fifth coil, the sixth coil, the seventh coil, and the eighth coil are disposed so as to face the first coil, the second coil, the third coil, and the fourth coil, respectively,
wherein a distance between an upper surface of the first wiring layer and a lower surface of the second wiring layer is a first distance, and
wherein the metal film is formed on each of the plurality of wiring layers disposed on the peripheral region so as to be spaced apart from the fifth coil and the sixth coil by the first distance or more as well as to be spaced apart from the seventh coil and the eight coil by the first distance or more in cross-sectional view.
